(19) United States
(12) Patent Application Publication
(10) Pub. No.: US 2025/0081487 A1
(43) Pub. Date: Mar. 6, 2025

(54) BIPOLAR JUNCTION TRANSISTOR WITH VARYING CONCENTRATION OF NARROW BANDGAP MATERIAL IN BASE STRUCTURE

(71) Applicant: Skyworks Solutions, Inc., Irvine, CA (US)

(72) Inventors: Guoliang Zhou, Walpole, MA (US); Cristian Cismaru, Newbury Park, CA (US); Bin Li, Camarillo, CA (US); Kai Hay Kwok, Burlington, MA (US); Yingying Yang, Newbury Park, CA (US); Andre G. Metzger, Newbury Park, CA (US); Viswanathan Ramanathan, Thousand Oaks, CA (US)

(21) Appl. No.: 18/825,980

(22) Filed: Sep. 5, 2024

Related U.S. Application Data
(60) Provisional application No. 63/536,907, filed on Sep. 6, 2023.
(60) Provisional application No. 63/544,032, filed on Oct. 13, 2023.
(60) Provisional application No. 63/544,024, filed on Oct. 13, 2023.
(60) Provisional application No. 63/544,040, filed on Oct. 13, 2023.

(51) Int. Cl. H01L 29/737; H01L 29/08; H01L 29/10; H01L 29/205

(52) U.S. Cl. CPC H10D 10/821; H10D 62/136; H10D 62/138; H10D 62/177; H10D 62/824

(57) ABSTRACT

A bipolar junction transistor has a collector over a substrate, a base over the collector, and an emitter over the base. The base includes a III-V ternary semiconductor alloy including first, second, and third elements, and having a narrower bandgap than a binary semiconductor alloy including only the first and second elements. At least a portion of the base has a differential concentration of the third element such that a concentration of the third element at a first location in the base is greater than at a second location in the base, the second location between the first location and the collector.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Technical Field

Embodiments of this disclosure relate to bipolar junction transistors.

### Description of Related Technology

Bipolar transistors, such as heterojunction bipolar transistors (HBTs), are implemented in a wide variety of applications. Such bipolar transistors can be formed on semiconductor substrates, such as gallium arsenide (GaAs) substrates. An example application for a bipolar transistor is in a power amplifier system. In some cases, specifications for power amplifier systems can be demanding to meet.

In an HBT, different semiconductor materials are utilized for the emitter and base regions to yield a heterojunction. Such a configuration can allow HBTs to be particularly useful in radio-frequency (RF) applications, including high-efficiency RF power amplifiers.

### SUMMARY

In some aspects, the techniques described herein relate to a bipolar junction transistor including: a substrate; a collector over the substrate; a base over the collector, the base including a III-V ternary semiconductor alloy including first, second, and third elements, the III-V ternary semiconductor alloy having a narrower bandgap than a binary semiconductor alloy including only the first and second elements, at least a portion of the base having a differential concentration of the third element such that a concentration of the third element at a first location in the base is greater than at a second location in the base, the second location between the first location and the collector; and an emitter over the base.

In some aspects, the techniques described herein relate to a bipolar junction transistor wherein the collector includes a gallium arsenide (GaAs) layer.

In some aspects, the techniques described herein relate to a bipolar junction transistor wherein the third element of the base is antimony (Sb) or indium (In).

In some aspects, the techniques described herein relate to a bipolar junction transistor wherein the III-V ternary semiconductor alloy of the base is gallium arsenide antimonide (GaAsSb) or indium gallium arsenide (InGaAs).

In some aspects, the techniques described herein relate to a bipolar junction transistor wherein the emitter includes an indium gallium phosphide (InGaP) layer.

In some aspects, the techniques described herein relate to a bipolar junction transistor wherein a concentration of the third element at the first location is in a range of 0.1% to 6% mole fraction.

In some aspects, the techniques described herein relate to a bipolar junction transistor wherein a concentration of the third element at the second location is zero.

In some aspects, the techniques described herein relate to a bipolar junction transistor wherein a concentration of the third element at a third location between the first and second locations is less than the concentration of the third element at the first location and greater than the concentration of the third element at the second location.

In some aspects, the techniques described herein relate to a bipolar junction transistor further including a sub-collector between the substrate and the collector.

In some aspects, the techniques described herein relate to a bipolar junction transistor wherein the base has a gradation of the concentration of the third element.

In some aspects, the techniques described herein relate to a bipolar junction transistor wherein a bandgap of the III-V ternary semiconductor alloy is in a range between 50% and 90% of a bandgap of the binary semiconductor alloy.

In some aspects, the techniques described herein relate to a bipolar junction transistor including: a substrate; a first n-type structure over the substrate; a p-type structure over the first n-type structure, the p-type structure including a III-V ternary semiconductor alloy including first, second, and third elements, the ternary semiconductor alloy having a narrower bandgap than a binary semiconductor alloy consisting of the first and second elements, at least a portion of the p-type structure having a differential concentration of the third element such that a concentration of the third element at a first location in the p-type structure is greater than at a second location in the p-type structure, the second location between the first location and the first n-type structure; and a second n-type structure over the p-type structure.

In some aspects, the techniques described herein relate to a bipolar junction transistor wherein the first n-type structure includes a gallium arsenide (GaAs) layer and the second n-type structure includes an indium gallium phosphide (InGaP) layer.

In some aspects, the techniques described herein relate to a bipolar junction transistor wherein the p-type structure includes a gallium arsenide antimonide (GaAsSb) layer or an indium gallium arsenide (InGaAs) layer.

In some aspects, the techniques described herein relate to a bipolar junction transistor wherein a concentration of the third element at the first location is in a range of 0.1% to 6% mole fraction of the III-V ternary semiconductor alloy.

In some aspects, the techniques described herein relate to a bipolar junction transistor further including a sub-collector between the substrate and the first n-type structure.

In some aspects, the techniques described herein relate to a bipolar junction transistor wherein the p-type structure has a gradation of the concentration of the third element.

In some aspects, the techniques described herein relate to a radio frequency device including: a bipolar junction transistor power amplifier having a collector, a base structure over the collector, and an emitter over the base structure, the base including a III-V ternary semiconductor alloy including first, second, and third elements, the III-V ternary semiconductor alloy having a narrower bandgap than a binary semiconductor alloy including only the first and second elements, at least a portion of the base structure having a differential concentration of the third element such that a concentration of the third element at a first location in the base is greater than at a second location in the base, the second location between the first location and the collector; and an antenna coupled to the bipolar junction transistor power amplifier.

In some aspects, the techniques described herein relate to a radio frequency device wherein the collector includes a gallium arsenide (GaAs) layer.

In some aspects, the techniques described herein relate to a radio frequency device wherein the third element of the base is antimony (Sb) or indium (In).

In some aspects, the techniques described herein relate to a radio frequency device wherein the III-V ternary semiconductor alloy of the base is gallium arsenide antimonide (GaAsSb) or indium gallium arsenide (InGaAs).

In some aspects, the techniques described herein relate to a bipolar junction transistor including: a substrate; a collector over the substrate; a base over the collector, the base including a III-V ternary semiconductor alloy including first, second, and third elements, the III-V ternary semiconductor alloy having a narrower bandgap than a binary semiconductor alloy including only the first and second elements, the base having a base contact formed thereon; and an emitter over the base, a ledge between the emitter and the base contact being 0.5 μm or less.

In some aspects, the techniques described herein relate to a bipolar junction transistor wherein the collector includes a gallium arsenide (GaAs) layer. In some aspects, the techniques described herein relate to a bipolar junction transistor wherein the base includes a gallium arsenide antimonide (GaAsSb) layer.

In some aspects, the techniques described herein relate to a bipolar junction transistor wherein the base includes an indium gallium arsenide (InGaAs) layer.

In some aspects, the techniques described herein relate to a bipolar junction transistor wherein the emitter includes an indium gallium phosphide (InGaP) layer.

In some aspects, the techniques described herein relate to a bipolar junction transistor wherein a concentration of the third element is in a range of 0.1% to 6% mole fraction of the III-V ternary semiconductor alloy.

In some aspects, the techniques described herein relate to a bipolar junction transistor wherein a ledge between the emitter and the base contact is in a range of 0.04 μm and 0.5 μm.

In some aspects, the techniques described herein relate to a bipolar junction transistor wherein a ledge between the emitter and the base contact is in a range of 0.14 μm and 0.5 μm.

In some aspects, the techniques described herein relate to a bipolar junction transistor wherein a ledge between the emitter and the base contact is in a range of 0.04 μm and 0.3 μm.

In some aspects, the techniques described herein relate to a bipolar junction transistor wherein a thickness of the base is 500 Å or less.

In some aspects, the techniques described herein relate to a bipolar junction transistor further including a sub-collector between the substrate and the collector.

In some aspects, the techniques described herein relate to a bipolar junction transistor wherein a bandgap of the III-V ternary semiconductor alloy is in a range between 50% and 90% of a bandgap of the binary semiconductor alloy.

In some aspects, the techniques described herein relate to a bipolar junction transistor including: a substrate; a first n-type structure over the substrate; a p-type structure over the first n-type structure, the p-type structure including a III-V ternary semiconductor alloy including first, second, and third elements, the ternary semiconductor alloy having a narrower bandgap than a binary semiconductor alloy consisting of the first and second elements, the p-type structure having a base contact formed thereon; and a second n-type structure over the p-type structure, a ledge between the second n-type structure and the base contact being 0.5 μm or less.

In some aspects, the techniques described herein relate to a bipolar junction transistor wherein the first n-type structure includes a gallium arsenide (GaAs) layer and the second n-type structure includes an indium gallium phosphide (InGaP) layer.

In some aspects, the techniques described herein relate to a bipolar junction transistor wherein the p-type structure includes a gallium arsenide antimonide (GaAsSb) layer or an indium gallium arsenide (InGaAs) layer.

In some aspects, the techniques described herein relate to a bipolar junction transistor wherein a concentration of the third element is in a range of 0.1% to 6% mole fraction of the III-V ternary semiconductor alloy.

In some aspects, the techniques described herein relate to a bipolar junction transistor wherein the ledge between the second n-type structure and the base contact being in a range of 0.04 μm and 0.3 μm.

In some aspects, the techniques described herein relate to a bipolar junction transistor wherein a thickness of the p-type structure being 500 Å or less.

In some aspects, the techniques described herein relate to a bipolar junction transistor further including a sub-collector between the substrate and the first n-type structure.

In some aspects, the techniques described herein relate to a radio frequency device including: a bipolar junction transistor power amplifier having a collector, a base over the collector, and an emitter over the base, the base including a III-V ternary semiconductor alloy including first, second, and third elements, the III-V ternary semiconductor alloy having a narrower bandgap than a binary semiconductor alloy including only the first and second elements, the base having a base contact formed thereon, and a ledge between the emitter and the base contact being 0.5 μm or less; and an antenna coupled to the bipolar junction transistor power amplifier.

In some aspects, the techniques described herein relate to a radio frequency device wherein the collector includes a gallium arsenide (GaAs) layer, the base includes a gallium arsenide antimonide (GaAsSb) layer or an indium gallium arsenide (InGaAs) layer, the emitter includes an indium gallium phosphide (InGaP) layer, and a concentration of the third element is in a range of 0.1% to 6% mole fraction of the III-V ternary semiconductor alloy.

In some aspects, the techniques described herein relate to a bipolar junction transistor including: a substrate; a collector over the substrate; a multi-layer base structure over the collector, the multi-layer base structure including a first layer having a first III-V semiconductor alloy and a second layer having a second III-V semiconductor alloy having a different composition of elements than the first III-V semiconductor alloy, the second layer having a narrower bandgap than the first layer, the first layer positioned between the collector and the second layer; and an emitter over the base structure.

In some aspects, the techniques described herein relate to a bipolar junction transistor wherein the collector includes a gallium arsenide (GaAs) layer.

In some aspects, the techniques described herein relate to a bipolar junction transistor wherein the second III-V semiconductor alloy of the base is gallium arsenide antimonide (GaAsSb).

In some aspects, the techniques described herein relate to a bipolar junction transistor wherein the second III-V semiconductor alloy of the base is or indium gallium arsenide (InGaAs).

In some aspects, the techniques described herein relate to a bipolar junction transistor wherein the emitter includes an indium gallium phosphide (InGaP) layer.

In some aspects, the techniques described herein relate to a bipolar junction transistor wherein a concentration of an element in the second layer that is not included in the first layer is in a range of 0.1% to 6% mole fraction.

In some aspects, the techniques described herein relate to a bipolar junction transistor wherein a concentration of the element in the first layer is zero.

In some aspects, the techniques described herein relate to a bipolar junction transistor wherein a concentration of a narrow bandgap material in a third layer between the first and second layers is less than the concentration of the third material in the second layer and greater than the concentration of the third material in the first layer.

In some aspects, the techniques described herein relate to a bipolar junction transistor further including a sub-collector between the substrate and the collector.

In some aspects, the techniques described herein relate to a bipolar junction transistor wherein the first layer has a gradation of a concentration of a narrow bandgap material.

In some aspects, the techniques described herein relate to a bipolar junction transistor wherein a bandgap of the second III-V semiconductor alloy is in a range between 50% and 90% of a bandgap of the first III-V semiconductor alloy.

In some aspects, the techniques described herein relate to a bipolar junction transistor including: a substrate; a first n-type structure over the substrate; a multi-layer p-type structure over the first n-type structure, the multi-layer p-type structure including a first layer having a first III-V semiconductor alloy and a second layer having a second III-V semiconductor alloy having a different composition of elements than the first III-V semiconductor alloy, the second layer having a narrower bandgap than first layer, the first layer positioned between the first n-type structure and the second layer; and a second n-type structure over the multi-layer p-type structure.

In some aspects, the techniques described herein relate to a bipolar junction transistor wherein the first n-type structure includes a gallium arsenide (GaAs) layer and the second n-type structure includes an indium gallium phosphide (InGaP) layer.

In some aspects, the techniques described herein relate to a bipolar junction transistor wherein the p-type structure includes a gallium arsenide antimonide (GaAsSb) layer or an indium gallium arsenide (InGaAs) layer.

In some aspects, the techniques described herein relate to a bipolar junction transistor wherein a concentration of an element in the second layer that is not included in the first layer is in a range of 0.1% to 6% mole fraction.

In some aspects, the techniques described herein relate to a bipolar junction transistor further including a sub-collector between the substrate and the first n-type structure.

In some aspects, the techniques described herein relate to a bipolar junction transistor wherein the first layer has a gradation of a concentration of a narrow bandgap material.

In some aspects, the techniques described herein relate to a radio frequency device including: a bipolar junction transistor power amplifier having a collector, a multi-layer base structure over the collector, and an emitter over the base structure, the multi-layer base structure including a first layer having a first III-V semiconductor alloy and a second layer having a second III-V semiconductor alloy having a different composition of elements than the first III-V semiconductor alloy, the second layer having a narrower bandgap than the first layer, the first layer positioned between the collector and the second layer; and an antenna coupled to the bipolar junction transistor power amplifier.

In some aspects, the techniques described herein relate to a radio frequency device wherein the collector includes a gallium arsenide (GaAs) layer.

In some aspects, the techniques described herein relate to a radio frequency device wherein the base includes antimony (Sb) or indium (In).

In some aspects, the techniques described herein relate to a radio frequency device wherein the second III-V semiconductor alloy of the base is gallium arsenide antimonide (GaAsSb) or indium gallium arsenide (InGaAs).

In some aspects, the techniques described herein relate to a bipolar junction transistor including: a substrate; a collector structure over the substrate; a base structure over the collector structure, the base structure including a III-V ternary semiconductor alloy, the base structure having a base contact formed thereon; and an emitter structure over the base structure, a ledge between the emitter structure and the base contact being 0.3 μm or less.

In some aspects, the techniques described herein relate to a bipolar junction transistor wherein the collector structure includes a gallium arsenide (GaAs) layer.

In some aspects, the techniques described herein relate to a bipolar junction transistor wherein the III-V ternary semiconductor alloy of the base structure is gallium arsenide antimonide (GaAsSb) or indium gallium arsenide (InGaAs).

In some aspects, the techniques described herein relate to a bipolar junction transistor wherein the emitter structure includes an indium gallium phosphide (InGaP) layer.

In some aspects, the techniques described herein relate to a bipolar junction transistor wherein the ledge between the emitter structure and the base contact is in a range of 0.04 μm and 0.3 μm.

In some aspects, the techniques described herein relate to a bipolar junction transistor wherein the ledge between the emitter structure and the base contact is in a range of 0.14 μm and 0.3 μm.

In some aspects, the techniques described herein relate to a bipolar junction transistor wherein the ledge between the emitter structure and the base contact is in a range of 0.1 μm to 0.2 μm.

In some aspects, the techniques described herein relate to a bipolar junction transistor wherein a thickness of the base structure is in a range of 100 Å to 500 Å.

In some aspects, the techniques described herein relate to a bipolar junction transistor wherein a thickness of the base structure is in a range of 200 Å to 400 Å.

In some aspects, the techniques described herein relate to a bipolar junction transistor further including a sub-collector between the substrate and the collector structure.

In some aspects, the techniques described herein relate to a bipolar junction transistor including: a substrate; a collector structure over the substrate; a base structure over the collector, the base structure including a III-V ternary semiconductor alloy, the base structure having a base contact formed thereon, a thickness of the base structure being 500 Å or less; and an emitter structure over the base structure, a ledge between the emitter structure and the base contact being 0.5 μm or less.

In some aspects, the techniques described herein relate to a bipolar junction transistor wherein the collector structure includes a gallium arsenide (GaAs) layer.

In some aspects, the techniques described herein relate to a bipolar junction transistor wherein the III-V ternary semiconductor alloy of the base structure is gallium arsenide antimonide (GaAsSb) or indium gallium arsenide (InGaAs).

In some aspects, the techniques described herein relate to a bipolar junction transistor wherein the emitter structure includes an indium gallium phosphide (InGaP) layer.

In some aspects, the techniques described herein relate to a bipolar junction transistor wherein the ledge between the emitter structure and the base contact being in a range of 0.04 μm and 0.5 μm.

In some aspects, the techniques described herein relate to a bipolar junction transistor wherein the ledge between the emitter structure and the base contact being in a range of 0.04 μm and 0.3 μm.

In some aspects, the techniques described herein relate to a bipolar junction transistor wherein the ledge between the emitter structure and the base contact being in a range of 0.1μ m to 0.3μ m.

In some aspects, the techniques described herein relate to a bipolar junction transistor wherein a thickness of the base structure is in a range of 100 Å to 500 Å.

In some aspects, the techniques described herein relate to a radio frequency device including: a bipolar junction transistor power amplifier having a collector, a base structure over the collector, and an emitter over the base structure, the base structure including a III-V ternary semiconductor alloy, the base structure having a base contact formed thereon; and an emitter structure over the base structure, a ledge between the emitter structure and the base contact being 0.3 μm or less; and an antenna coupled to the bipolar junction transistor power amplifier.

In some aspects, the techniques described herein relate to a radio frequency device wherein the collector structure includes a gallium arsenide (GaAs) layer, the III-V ternary semiconductor alloy of the base structure is gallium arsenide antimonide (GaAsSb) or indium gallium arsenide (InGaAs), the emitter structure includes an indium gallium phosphide (InGaP) layer, and the ledge between the emitter structure and the base contact is in a range of 0.04 μm and 0.3 μm.

### BRIEF DESCRIPTION OF THE DRAWINGS

Embodiments of this disclosure will now be described, by way of non-limiting example, with reference to the accompanying drawings.

FIG. 1 is a schematic cross-sectional side view of a heterojunction bipolar transistor (HBT) according to an embodiment.

FIG. 2 is a graph showing a current gain as a function of a ledge dimension.

FIG. 3 is a graph showing simulation results indicating a relationship between a beta ratio and a concentration (mole fraction) of antimony (Sb) in a base layer of HBTs.

FIG. 4 is a graph showing a relationship between a beta ratio (Br2) and a thickness of a base in an HBT.

FIG. 5 is graph showing current-voltage (I-V) curves of conventional HBT devices near saturation region with different knee voltages (Vk) and lower collector-emitter voltage offsets (Vceoffset).

FIG. 6A shows heterojunction bipolar transistor circuitry.

FIG. 6B is a schematic cross-sectional side view of an HBT.

FIG. 7 is a graph showing maximum power output values of heterojunction bipolar transistor (HBT) power amplifiers (PAs) with different antimony (Sb) concentrations in a base for different base resistance (Rb) values through a load-pull measurement.

FIG. 8A is a schematic cross-sectional side view of an HBT according to an embodiment.

FIG. 8B is a schematic cross-sectional side view of an HBT according to another embodiment.

FIG. 9 is a schematic cross-sectional side view of an HBT according to another embodiment.

FIGS. 10A-10E show example emitter/base/collector stacks in the HBT of FIG. 8A.

FIG. 11 is a graph showing turn-on voltage of an InGaP/GaAs1-xSbx/GaAs (emitter/base/collector) stack HBT with different Sb composition or concentration.

FIG. 12 schematically shows a module that includes one or more HBTs, which can be any of the HBTs described herein.

FIG. 13A schematically shows a radio frequency (RF) device that includes one or more HBTs, which can be any of the HBTs described herein.

FIG. 13B schematically shows a wireless device, which can include any of the HBTs described herein.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

A heterojunction bipolar transistor (HBT) is a type of bipolar transistor that incorporates distinct semiconductor materials for its emitter and base. HBTs can improve performance characteristics as compared to their homojunction counterparts. The heterojunction interface can enhance carrier injection and movement within the device, enabling higher frequency operation, reduced noise, and increased power-handling capabilities.

In the realm of radio frequency (RF) devices, the HBTs find a valuable application as power amplifiers (PAS). A power amplifier's primary function in RF devices can be to take a relatively weak RF input signal and elevate its power level while upholding signal integrity. HBTs are well-suited for this role due to their capacity to manage higher power levels and function at elevated frequencies, which standard transistors may struggle to achieve.

There is a continuing demand to improve HBT gain, power added efficiency (PAE), and linearity at higher frequency (e.g., at 5G/6G wireless frequency ranges). The HBT gain affects the amplification efficacy of the power amplifier. This metric signifies the ratio of the output voltage to the input voltage. Within an HBT-based power amplifier, achieving substantial gain can be significant for amplifying signal power without introducing distortions that could compromise signal fidelity. The PAE can relate to the power amplifier's efficiency in converting current (e.g., a direct current (DC) power) into radio frequency (RF) output power. Calculated as the ratio of the RF output power added to the DC power input, a high PAE value indicates efficient power conversion, minimizing wastage and heat generation, particularly significant for energy conservation and prolonged battery life in portable devices.

An emitter-base ledge, a distance between an emitter and a base contact of the HBT, can affect the gain and/or the PAE in HBT amplifiers. A wider ledge can increase a base-collector (b-c) junction capacitance and a base resistance, both of which may contribute to degrade the device performance, especially at a high frequency. In order to enable high-speed, high-power, high-linearity, and highly reliable devices at higher frequency, the ledge may be minimized. However, as the ledge dimension decreases, there may be a significant drop of current gain or beta due to, for example, the increase of base recombination current through the shortened ledge. Therefore, it can be crucial to enable ledge dimension reduction while mitigating or preventing the significant drop of current gain or beta.

A knee voltage (Vk) and a turn-on voltage (Vbe) are related to the PAE. The knee voltage and the turn-on voltage correspond to the voltage thresholds at which the HBT starts conducting current between the emitter and base regions. The knee voltage and the turn-on voltage values are crucial for properly biasing the HBT to achieve desired amplification characteristics. When the turn-on voltage is reduced, the knee voltage can be reduced, thereby achieving a lower collector-emitter voltage offset (V_{ceoffset}). The narrower bandgap of the base layer reduces the turn-on voltage of base-emitter (BE) junction and reduces the collector-emitter voltage offset. However, when narrowing the bandgap of the base layer, a higher base resistance due to, for example, lowered hole mobility and/or lattice constant increase in the base layer of the HBT.

Various embodiments disclosed herein relate to bipolar junction transistors with improved device performance, such as reduced surface recombination, reduced knee, and/or improved PAE. A bipolar junction transistor according to an embodiment can include a substrate, a collector over the substrate, a base over the collector, and an emitter over the base. The substrate can be a semiconductor substrate, such as a gallium arsenide (GaAs) substrate, or a silicon (Si) substrate. In some embodiments, the bipolar junction transistor can be an NPN transistor in which the collector and the emitter include N-type semiconductors, and the base includes a P-type semiconductor. The collector can include gallium arsenide (GaAs), such as an N-type GaAs(N-GaAs). The emitter can include indium gallium phosphide (InGaP), such as an N-type InGaP(N-InGaP). The base can include a III/V ternary semiconductor alloy. In some embodiments, the base can include a III/V ternary semiconductor alloy including a first element, a second element, and a third element. The ternary semiconductor alloy with the first, second, and third elements can have a narrower bandgap than a binary semiconductor alloy including only the first and second elements. In some embodiments, at least a portion of the base can have a differential concentration of the third material such that a concentration of the third material at a first location in the base is greater than at a second location in the base, where the second location is positioned between the first location and the collector. In some embodiments, the base can have a multi-layer base structure. The multi-layer base structure can include a first layer including a first III/V semiconductor alloy and the second layer including a second III/V semiconductor alloy having a different composition of elements than the first III/V semiconductor alloy. The second layer has a narrower bandgap than the first layer. The first layer is positioned between the collector and the second layer. In some embodiments, a ledge between the emitter and a base contact that is formed on the base is 0.5 μm or less, 0.4 μm or less, or 0.3 μm or less. In some embodiments, a thickness of the base is 500 Å or less, 400 Å or less, or 300 Å or less.

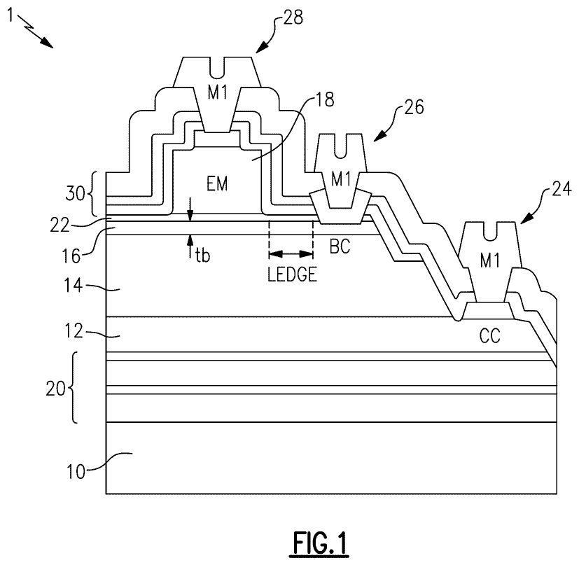

FIG. 1 is a schematic cross-sectional side view of a heterojunction bipolar transistor (HBT) 1. The HBT I can include a substrate 10, a sub-collector 12 over the substrate 10, a collector 14 over the sub-collector 12, a base 16 over the sub-collector 12, and an emitter 18 over the base 16. There may be one or more intermediate layers 20, 22 between the substrate 10 and the sub-collector 12 or between the base 16 and the emitter 18. The HBT I can include a collector contact 24 on the sub-collector 12, a base collector 26 on the base, and an emitter contact 28 on the emitter 18. The HBT I can include one or more cover layers 30. For example, the cover layer 30 may include a protective layer, a passivation layer, or a capping layer. In some embodiments, the HBT I can be an NPN transistor in which the collector 14 and the emitter 18 are N-type semiconductors, and the base 16 is a P-type semiconductor.

The substrate 10 can be a semiconductor substrate, such as a gallium arsenide (GaAs) substrate. In other embodiments, the substrate 10 can include indium phosphide, gallium nitride, or other type of semiconductor material. The substrate 10 can include any other suitable substrate material can be used, such as silicon (Si).

The sub-collector 12 can provide a low-resistance conduit for current flow between the collector 14 and the substrate 10. The sub-collector 12 can include silicon (Si), germanium (Ge), silicon-germanium (SiGe) alloys, and III-V compound semiconductors, such as gallium arsenide (GaAs) or indium phosphide (InP). In embodiments, the sub-collector 12 may also include an N-type semiconductor, such as an N-type GaAs(N-GaAs).

The collector 14 can contribute to efficient charge carrier collection and influencing the device's overall performance. The collector 14 can include silicon (Si), germanium (Ge), silicon-germanium (SiGe) alloys, and III-V compound semiconductors, such as gallium arsenide (GaAs) or indium phosphide (InP). In some embodiments, the sub-collector 12 and the collector 14 may be made of the same material. For example, the collector 14 can include gallium arsenide (GaAs), such as an N-type GaAs(N-GaAs).

The base 16 can have an opposite type doping as the emitter and the collector. The base can function as a control element in regulating the flow of charge carriers between the emitter 18 and the collector 14. When the base-emitter junction is forward-biased, electrons move from the emitter 18 into the base 16. A majority of the electrons then diffuse across the narrow base 16 due to its doping. This diffusion process can form the basis of current amplification. As these electrons cross the base 16, only a fraction recombines with the holes present, while the majority continues into the collector 14, resulting in a greater collector current. Accordingly, the HBT 1 can be an amplifier or a switch in some embodiments.

The emitter 18 can include silicon (Si), germanium (Ge), silicon-germanium (SiGe) alloys, and III-V compound semiconductors, such as gallium arsenide (GaAs) or indium phosphide (InP). In some embodiments, the emitter can include indium gallium phosphide (InGaP), such as an N-type InGaP(N-InGaP).

The one or more intermediate layers 20, 22 can include a buffer layer, a graded layer, a strain-compensation layer, a selective epitaxy layer, a dislocation-filtering layer, or a doping adjustment layer.

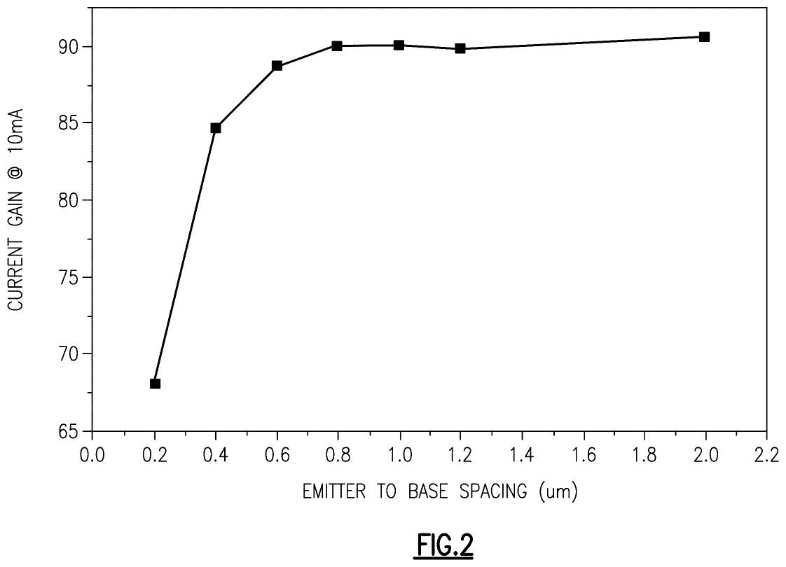

A ledge can be defined between the emitter 18 and the base contact 26. A surface recombination can be reduced through the ledge. Some ledge designs that have a relatively long or wide ledge can increase a base-collector (b-c) junction area, which may in turn increase b-c junction capacitance and base resistance, both of which degrade the device performance, especially at a relatively high frequency. Therefore, a short or narrow ledge may be preferred. However, depending on the composition of the HBT structure, a short or narrow ledge (e.g., less than 0.5 μm) can result in a significant drop of current gain or beta due to the increase of base recombination current through the shortened ledge (see FIG. 2). Also, certain HBT designs may introduce a relatively high ledge current leakage, which can reduce current gain in the HBT. Materials and/or dimensions of the base 16 of the embodiments of the present disclosure enable the HBT 1 to have a relatively short ledge, such that the surface recombination is reduced, while maintaining a sufficiently high current gain and/or beta. The beta can be calculated by dividing the collector current by the base current, or dividing the emitter current by the base current and subtracting the quotient.

In some embodiments, the base 16 can include a III/V ternary semiconductor alloy. In some embodiments, the base 16 can include a III/V ternary semiconductor alloy including a first element, a second element, and a third element. The ternary semiconductor alloy with the first, second, and third elements can have a narrower bandgap than a binary semiconductor alloy including only the first and second elements. A concentration or amount of the third element in the base 16 can be relatively small (e.g., at least 0.1% mole fraction of the base 16, 0.1% to 6% mole fraction of the base 16, or 0.1% to 1%, 2%, 3%, 4%, 5%, or any other value less than 6% mole fraction of the base 16) as compared to the first and second elements. The concentration (e.g., mole fraction) or amount of the third element in the base 16 can be greater than 6% in some embodiments. Thus, the third element can be referred to as a narrow bandgap element. The concentration of the third element can be relatively low, and a combination of the first and second element can define the majority of the base 16. Therefore, the combination of the first and second element can be referred to as a primary material of the base 16 and the third element can be referred to as a narrow bandgap element or an additive. A greater concentration or amount of the third element (e.g., Sb) in the base 16 can create a greater lattice mismatch between the base 16 and the collector 14. In order to maintain an optimal crystal quality, the concentration of the third element can be selected to be below a certain concentration for a certain thickness of the base 16. For example, when the thickness of the base 16 is about 750 Å, the certain concentration can be about 6%. When the thickness of the base 16 is thinner, the certain concentration can be higher (e.g., higher than 6% for a thickness of the base 16 less than 750 Å). For example, a combination of the first and second elements can define a gallium arsenide (GaAs), and the third element can be antimony (Sb) or indium (In).

The bandgap values Eg(in eV) of GaAs₁₋ₓSbₓ with x between 0 and 0.4 can be derived by the following equation: Eg=1.2x²−1.9x+1.43. The equation indicates that, with x between 0 and 0.4, as the concentration of the third element (e.g., Sb) increases, the bandgap decreases. For example, as compared to the bandgap Eg(0) for GaAs (x=0), the bandgap value Eg(0.1) of GaAsSb with Sb concentration of x=0.1 is about 0.88Eg(0), the bandgap value Eg(0.15) of GaAsSb with Sb concentration of x=0.15 is about 0.82Eg(0), the bandgap value Eg(0.225) of GaAsSb with Sb concentration of x=0.225 is about 0.75Eg(0), the bandgap value Eg(0.25) of GaAsSb with Sb concentration of x=0.25 is about 0.73Eg(0), and the bandgap value Eg(0.3) of GaAsSb with Sb concentration of x=0.3 is about 0.68Eg(0). In some embodiments, a band gap of the ternary semiconductor alloy with the first, second, and third elements can be in a range between, for example 95% and 50%, 90% and 50%, 85% and 50%, 80% and 50%, 95% and 60%, 90% and 60%, 90% and 70%, or 85% and 60 of a bandgap of a binary semiconductor alloy including only the first and second elements.

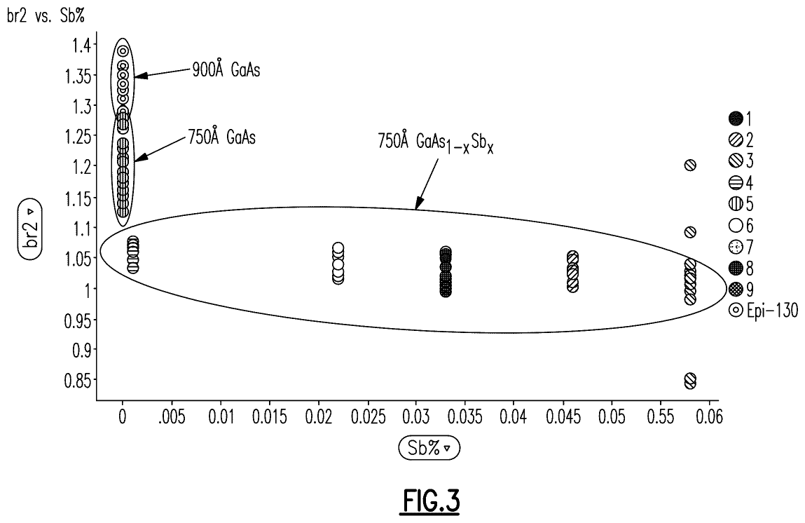

The addition of the narrow bandgap material (the third element) in the base 16 enables the HBT 1 to have a relatively short ledge, such that the surface recombination is reduced, while maintaining a sufficiently high current gain and/or beta. In some embodiments, the addition of the narrow bandgap material enables the ledge of the HBT 1 to be 0.5 μm or less, 0.4 μm or less, or 0.3 μm or less, without significantly reducing the current gain and/or beta. For example, the ledge of the HBT I can be in a range of 0.04 μm to 0.5 μm, 0.1 μm to 0.5 μm, 0.14 μm to 0.5 μm, 0.04 μm to 0.4 μm, 0.04 μm to 0.3 μm, 0.1 μm to 0.3 μm, 0.1 μm to 0.2 μm, 0.1 μm to 0.4 μm, or 0.14 μm to 0.3 μm. In some embodiments, the minimum dimension of the ledge can be a thickness of one or more of the cover layers 30. The significance of the addition of the narrow bandgap material will be described further with respect to FIG. 3.

In some embodiments, a thickness tb of the base 16 can be selected so as to enable reduction of the ledge dimension while maintaining a sufficiently high current gain and/or beta. The thickness tb of the base 16 according to some embodiments can be 500 Å or less, 400 Å or less, or 300 Å or less. For example, the thickness tb of the base 16 can be in a range between 100 Å and 500 Å, 200 Å and 500 Å, 100 Å and 400 Å, 200 Å and 400 Å, 100 Å and 300 Å, or 200 Å and 300 Å. With the thickness tb of the base 16 in any of these ranges, the ledge of the HBT 1 can be 0.5 μm or less, 0.4 μm or less, or 0.3 μm or less, or in a range of 0.04 μm to 0.5 μm, 0.1 μm to 0.5 μm, 0.14 μm to 0.5 μm, 0.04 μm to 0.4 μm, 0.04 μm to 0.3 μm, 0.1 μm to 0.4 μm, or 0.14 μm to 0.3 μm without significantly reducing the current gain and/or beta.

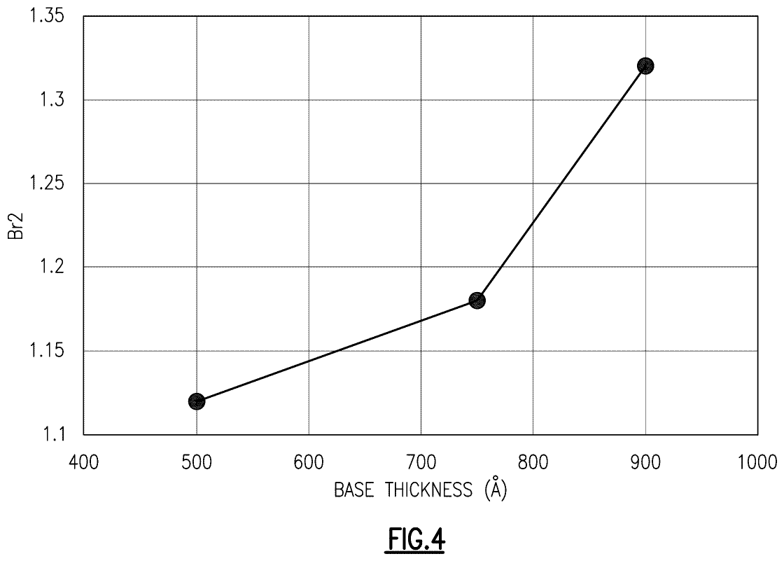

The selection of the thickness tb of the base 16 can have a significant impact on Br2 as described further with respect to FIG. 4. Because a thickness of a base in an HBT relates to current handling ability, base current, voltage breakdown, thermal stability, and reliability of the HBT 1, the thickness of the base may not be randomly selected, and in conventional HBTs can often be within a range between 700 Å and 900 Å. A thinner base thickness may reduce carrier transient time in the base 16, therefore can be beneficial for a device operating at higher frequency. However, thinner base can increase the difficulty of device process.

FIG. 2 is a graph showing a current gain as a function of ledge size (e.g., an emitter to base spacing) of a conventional HBT that includes an emitter that has an emitter size of 2×6 μm². The graph indicates that in a conventional HBT, when the ledge is significantly short or narrow (e.g., less than 0.5 μm), the HBT experience a significant drop of current gain or beta due to the increase of base recombination current through the shortened ledge.

FIG. 3 is a graph showing simulation results indicating a relationship between a beta ratio of two heterogeneous bipolar transistors (HBTs) and a concentration (mole fraction) of antimony (Sb) in a base layer of the HBTs. The beta ratio of 1 indicates that a reduction of the ledge does not affect the gain in the HBTs, while greater beta ratio indicates that the reduction of the ledge negatively impacts the gain in the HBTs. In the simulations, the two HBTs have the same structures except for the ledge dimension. One of the HBTs used in the simulation has a 2 μm ledge and the other has a 0.3 μm ledge, and the beta ratio Br2 is the beta of the 2 μm ledge device to the beta of the 0.3 μm ledge device. Various simulations were conducted with a 750 Å thick base and a 900 Å thick base. In the simulations, GaAs is used as a primary material of the base (the primary material may be the first and second elements of the III/V ternary semiconductor alloy disclosed herein). In the graph of FIG. 3, there are seven groups of simulation results including two groups at 0% concentration of Sb, which have shading patterns labeled Epi-130 and 5, one group at about 0.1% concentration of Sb, which has a shading pattern labeled 4, one group at about 2.25% concentration of Sb, which has a shading pattern labeled 9, one group at about 3.3% concentration of Sb, which has shading patterns labeled 1, 7, 8, 9, one group at about 4.6% concentration of Sb, which has a shading pattern labeled 2, and one group at about 5.8% concentration of Sb, which has a shading pattern labeled 3.

The simulation results of FIG. 3 indicate that the presence of Sb can improve the beta ratio, and a relatively small amount of the Sb concentration (0.1% mole fraction) is sufficient to provide significant improvements relative to no Sb in the base. For example, at the same base layer thickness of 750 Å, the beta ratio can be reduced by about 15% with a very tiny amount of Sb (0.1% mole fraction) incorporation into the GaAs base. Further, the increase of the Sb mole fraction in the base from about 0.1% to about 5.8% slightly improves the beta ratio.

This shows that inclusion of even a small amount of narrow bandgap element, such as antimony (Sb), in addition to a primary base material, such as gallium arsenide (GaAs), in terms of the base recombination current can optimize epitaxial structure for high performance HBTs. Ledge leakage suppression by a relatively small addition of the narrow bandgap element (e.g., Sb) provides options to achieve a narrow ledge (e.g., sub-micron ledge device) with conventional InGaP/GaAs like structures.

FIG. 4 is a graph showing a relationship between a beta ratio (Br2) and a thickness of a base in an HBT. The HBT used in FIG. 4 includes an n-type InGaP emitter and a p+GaAs base. Y-axis is the beta ratio between a 2 μm ledge and a 0.3 μm ledge of the same HBT. The graph of FIG. 4 indicates that at 900A base thickness, the current gain (or beta) of the HBT with 0.3 μm ledge is about 75% of that of a 2 μm ledge device, while at 500 Å base thickness, the current gain of a 0.3 μm ledge device can be as high as about 90% of that of a 2 μm ledge device. The results of FIG. 4 indicate that a current gain of an HBT with a relatively thin base (e.g., about 500 Å or less) may be maintained at a sufficiently high value even when the ledge is shortened or reduced.

The principles and advantages related to the addition of the narrow bandgap element in the base 16 and the reduction of the thickness tb of the base 16 as disclosed herein can be combined with each other in a single HBT, in some embodiments. Various combinations of the materials of the base 16, the thickness th of the base 16, and the ledge between the emitter 18 and the base contact 26 disclosed herein can enable an HBT with improved performance.

InGaP/GaAs single heterojunction HBTs (SHBTs) have been used and optimized for high power and high-speed applications, such as high efficiency microwave amplifiers for more than two decades. To improve device efficiency, such as power added efficiency (PAE), of the HBTs, the knee voltage (Vk) can be reduced. The Vk can be reduced by reducing the device turn on voltage (Vbe), thereby achieving a lower V_{ceoffset}.

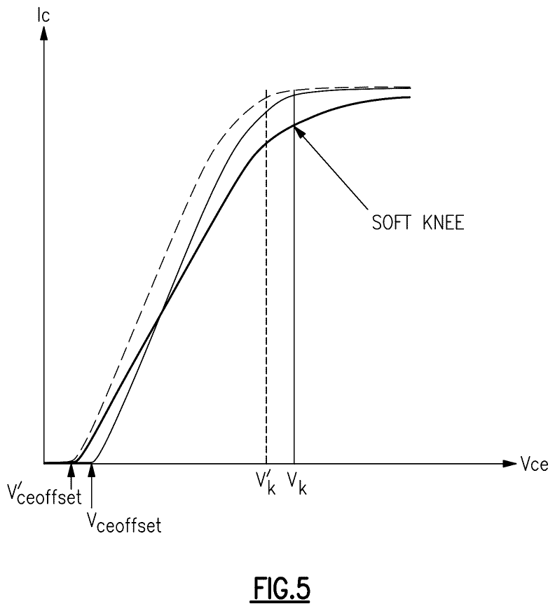

FIG. 5 is graph showing current-voltage (I-V) curves of conventional HBT devices near saturation region with different knee voltages (Vk) and lower collector-emitter voltage offsets (V_{ceoffset}).

Implementing a III/V ternary semiconductor alloy including a first, element, a second element, and a third element (e.g., GaAsSb) that has a narrower bandgap than a binary semiconductor alloy including only the first and second elements (e.g., GaAs) as a base of an HBT (e.g., an InGaP/GaAs based HBT) is attractive because of its narrower bandgap and, in the case of a GaAsSb base and a GaAs collector, its type-II band alignment between the GaAsSb base and the GaAs collector. The narrower bandgap of the base can reduce the turn-on voltage of base-emitter (BE) junction, resulting in reduced Veeoffset. A type-II band alignment between the base and the collector, such as between GaAsSb and GaAs, can eliminate or mitigate the current blockage caused by a conduction band offset between the base-collector (BC) junction, which is one of the causes to a soft knee (see FIG. 5). However, introducing a narrow bandgap element, such as Sb, into a primary material, such as GaAs, may cause higher base resistance due to, for example, decrease in hole mobility with the increase of Sb composition, or increase in lattice constant of GaAsSb with the increase of Sb composition. Therefore, the base thickness may be reduced to sustain a pseudomorphic crystal structure or a structure that has lattice mismatch. From the HBT device operation perspective, a high base resistance (Rb) not only degrades the device performance at higher frequencies (such as lowering the transition frequency), but also causes a soft knee which may overweigh the benefits gained from a lower Veeoffset (see FIG. 5).

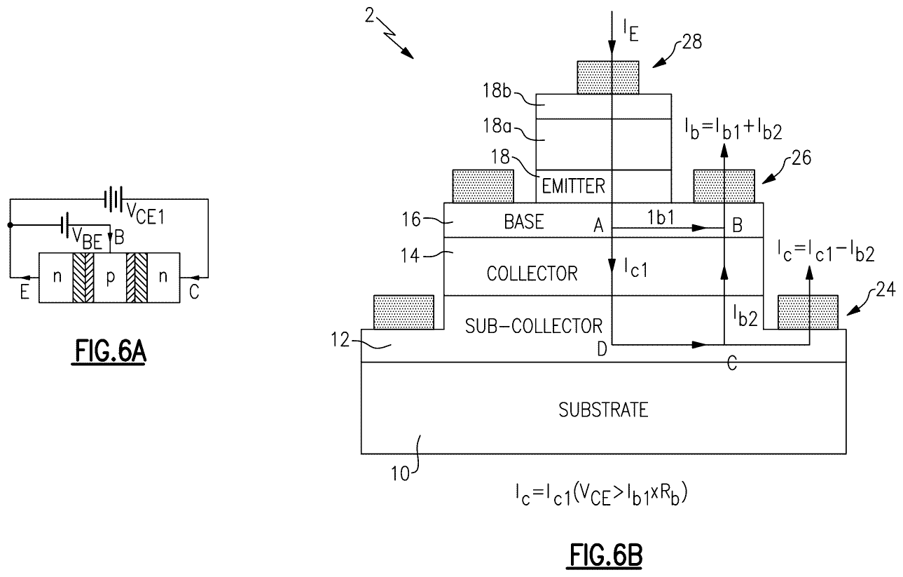

FIG. 6A shows a circuit diagram of a heterojunction bipolar transistor (HBT) 2. FIG. 6B is a schematic cross-sectional side view of the HBT 2. The HBT 2 can be an NPN transistor. Arrows in FIG. 6A indicate the current direction and arrows in FIG. 6B indicate the electron flow direction. The HBT 21 can include a substrate 10, a sub-collector 12 over the substrate 10, a collector 14 over the sub-collector 12, a base 16 over the sub-collector 12, and an emitter 18 over the base 16. The HBT 2 can include a collector contact 24 on the sub-collector 12, a base collector 26 on the base, and an emitter contact on the emitter 18. Unless otherwise noted, the components of FIGS. 6A-6B may be structurally and/or functionally the same as or generally similar to like components of FIG. 1.

When the HBT 2 is in a saturation mode, base-emitter (BE) and base-collector (BC) junctions are under forward biased condition. I_{E} is the total electron flux injected from the emitter 18 into the base 16, I_{b1} is a portion of the electron flux goes through the base 16 (base current) and recombined by electron-hole recombination in the base 16. I_{C1} is the remaining electron flux (I_{E}-I_{b1}) that enters into the collector 14. When the base resistance is significantly higher as compare to the BC junction resistance under the forward biased condition and the collector resistance, the voltage drop across the base 16 between point A and point B (I_{b1}×Rb) can be greater than the voltage drop across the BC junction between point A and point D (I_{C1}×(R_{be}+R_{c})), where R_{be} is the resistance of BC junction and Re is collector resistance. When the sub-collector 12 is heavily doped, the resistance between point D and point C can be ignored. Therefore, during the initial device turn-on stage, the potential at point C in the sub-collector 12 will be lower than that of point B in the base 16. There will be a portion of the electron flux that back flows from point C in the sub-collector 12 to point B in the base 16 (I_{b2}). In this case, Ic is equal to I_{C1}-I_{b2}. When I_{C1}×(R_{be}+R_{c}) is greater than I_{b1}×Rb, I_{b2} will become zero and I, can reach to the device situation current I_{c1}. From this illustration, a skilled artisan can observe that an HBT with a higher base resistance (Rb) will need higher collector-emitter voltage (Vce) to reach its saturation current and causes a softer knee. The collector current (Ic) remains equal to the value I_{c1} when the collector-emitter voltage (VCE) exceeds the product of the base current (I_{b1}) and the base resistance (R_{b}), which can be denoted as I_{C}=I_{C1}(V_{CE}>I_{b1}×R_{b}). In other words, once the voltage across the collector-emitter junction reaches a certain level determined by the base current and base resistance, the collector current can maintain a constant value corresponding to I_{C1}.

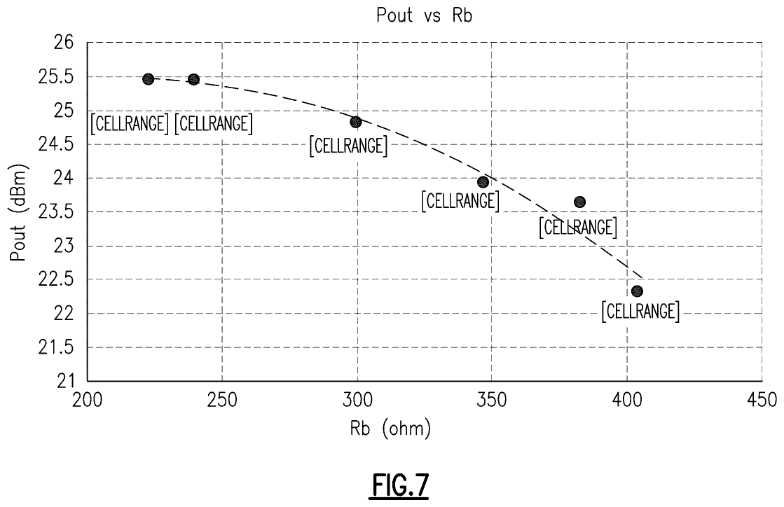

FIG. 7 is a graph showing maximum power output values of heterojunction bipolar transistor (HBT) power amplifiers (PAs) with different antimony (Sb) concentrations in the base for different base resistance (R_{b}) values through a load-pull measurement. The graph of FIG. 7 indicates that a lower device power output is obtained at a higher R_{b}.

Various embodiments disclosed herein relate to a heterojunction bipolar transistor (HBT) with a base that achieves a lower turn-on voltage Vbe without significantly increasing the base resistance Rb thereby preventing or mitigating a soft knee behavior. In some embodiments, the base can include a III-V ternary semiconductor alloy including first, second, and third elements having a narrower bandgap than a binary semiconductor alloy including only the first and second elements. For example, at least a portion of the base structure can have a differential concentration of the third material such that a concentration of the third material at a first location in the base is greater than at a second location in the base. For another example, the base can have a multi-layer base structure that includes a first layer including a first III/V semiconductor alloy and a second layer including a second III/V semiconductor alloy having a different composition of elements than the first III/V semiconductor alloy.

Although lower Vbe does not always lead to a lower V_{ceoffset} since the latter is determined by both the Vbe and the Vce, the embodiments disclosed herein can provide options to tailor the Vbe. The embodiments disclosed herein can be combined with any other embodiments disclosed herein to further tune the Vbe and the Vbc to achieve the suitable V_{ceoffset} and Vk, thereby providing an improved PAE.

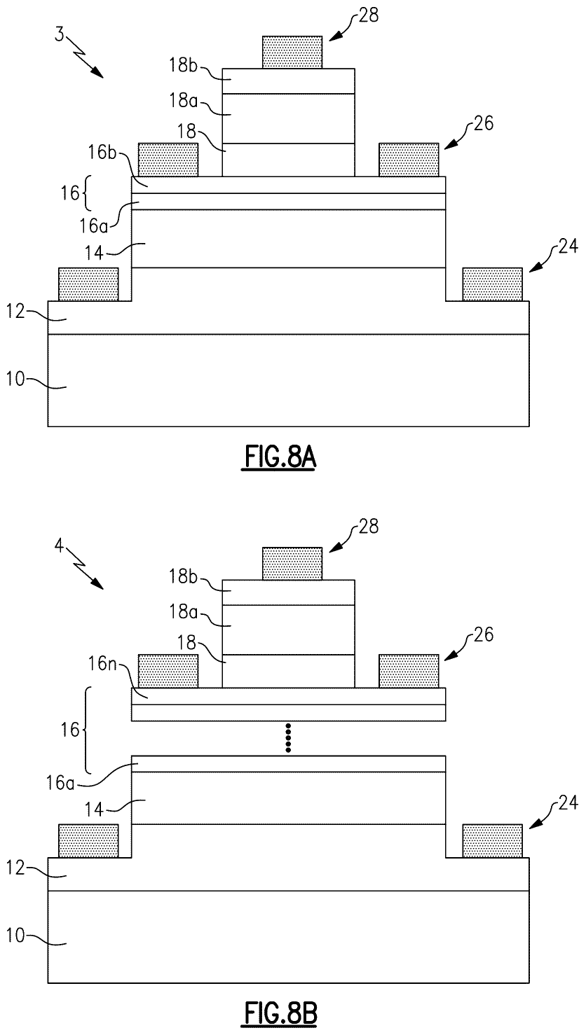

FIG. 8A is a schematic cross-sectional side view of a heterojunction bipolar transistor (HBT) 3. The HBT 3 can include a substrate 10, a sub-collector 12 over the substrate 10, a collector 14 over the sub-collector 12, a base 16 over the sub-collector 12, and an emitter 18 over the base 16. The HBT 3 can include an emitter cap 18a over the emitter 18, and an emitter contact 18b over the emitter cap 16a. The HBT 3 can include a collector contact 24 on the sub-collector 12, a base collector 26 on the base, and an emitter contact 28 on the emitter 18. The HBT 3 can include one or more cover layers (not shown), such as the cover layers 30 shown in FIG. 1. In some embodiments, the HBT 3 can be an NPN transistor in which the collector 14 and the emitter 18 are N-type semiconductors, and the base 16 is a P-type semiconductor. Unless otherwise noted, the components of FIG. 8A may be structurally and/or functionally the same as or generally similar to like components of FIGS. 1 and 6B.

The base 16 of the HBT 3 in FIG. 8A has a multi-layer (dual layer) base structure that includes a first layer 16a and a second layer 16b. The first layer 16a can include a first III/V semiconductor alloy and the second layer 16b can include a second III/V semiconductor alloy that has a different composition of elements than the first III/V semiconductor alloy. The second layer 16b has a narrower bandgap than the first layer 16a. The first layer 16a is positioned between the collector 14 and the second layer 16b. By having the first layer 16a, between the collector 14 and the second layer 16b, lattice mismatch between the second layer 16b and the collector 14 can be reduced, thereby achieving an improved performance (e.g., less current leakage, or improved power added efficiency (PAE)).

In some embodiments, the first III/V semiconductor alloy includes a first element, a second element, and a third element, and the second III/V semiconductor alloy includes the first and second elements but none of the third element, or less of the third element than the first III/V semiconductor alloy. A concentration or amount of the third element in the first layer 16a of the base 16 can be relatively small (e.g., 0.1% to 6% mole fraction of the base 16) as compared to the first and second elements. For example, the first III/V semiconductor alloy can be GaAsSb or InGaAs, and the second III/V semiconductor alloy can be GaAs or InGaAs. For another example, the first III/V semiconductor alloy can be GaAsSb or InGaAs, and the second III/V semiconductor alloy can be GaAsSb with lower Sb concentration than the first III/V semiconductor alloy or InGaAs with lower In concentration than the first III/V semiconductor alloy. The incorporation of the multi-layer base structure as the base 16 in the HBT 3 may introduce an additional barrier to electrons transport through the base 16.

FIG. 8B is a schematic cross-sectional side view of a heterojunction bipolar transistor (HBT) 4. The HBT 4 of FIG. 8B is generally similar to the HBT 3 of FIG. 8A except that FIG. 8B illustrates first to nth layers (16a-16n) of the base 16 in the HBT 4. FIG. 8B shows that the principles and advantages related to the dual layer base structure of the HBT 3 shown in FIG. 8A can be implemented with any number of layers of the base 16.

FIG. 9 is a schematic cross-sectional side view of a heterojunction bipolar transistor (HBT) 5. The HBT 5 can include a substrate 10, a sub-collector 12 over the substrate 10, a collector 14 over the sub-collector 12, a base 16 over the sub-collector 12, and an emitter 18 over the base 16. The HBT 5 can include a collector contact 24 on the sub-collector 12, a base collector 26 on the base, and an emitter contact on the emitter 18. The HBT 5 can include one or more cover layers (not shown). In some embodiments, the HBT 5 can be an NPN transistor in which the collector 14 and the emitter 18 are N-type semiconductors, and the base 16 is a P-type semiconductor. Unless otherwise noted, the components of FIG. 9 may be structurally and/or functionally the same as or generally similar to like components of FIGS. 1, 6B, 8A and 8B.

The base 16 can include a III-V ternary semiconductor alloy including first, second, and third elements. The III-V ternary semiconductor alloy has a narrower bandgap than a binary semiconductor alloy that includes only the first and second elements. At least a portion of the base 16 has a differential concentration of the third material such that a concentration of the third material at a first location 36 in the base 16 is greater than at a second location 38 in the base 16. The second location 38 is positioned between the first location 36 and the collector 14. Therefore, the first location 36 can be referred to as a narrow bandgap region and the second location 38 can be referred to as a wider bandgap region. By having the second location 38 with less third material concentration between the collector 14 and the first location 36, lattice mismatch between base 16 and the collector 14 can be reduced, thereby achieving an improved performance (e.g., less current leakage, or improved power added efficiency (PAE)).

In some embodiments, the base 16 can have a gradient (e.g., a continuous gradient) of the third element in which the concentration of the third element gradually decreases from the first location 36 to the second location 38. While FIG. 9 shows an embodiment in which the concentration gradually decreases in one contiguous base layer, in some other embodiments, the third element variation can be implemented in an HBT as a multi-layer base structure. For example, in some such embodiments, the concentration of the third element in each layer can decrease from the layer closes to the base (highest concentration) to the layer closest to the collector (least concentration).

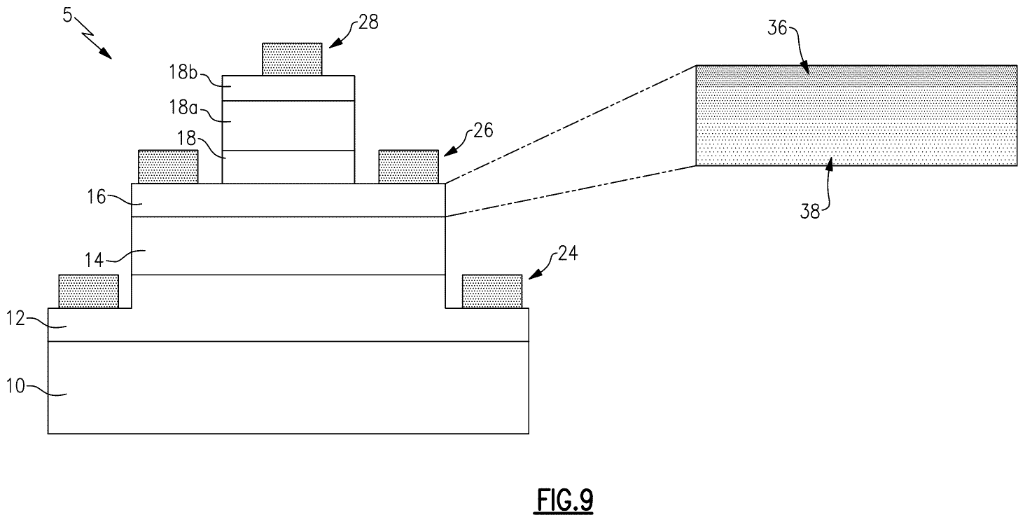

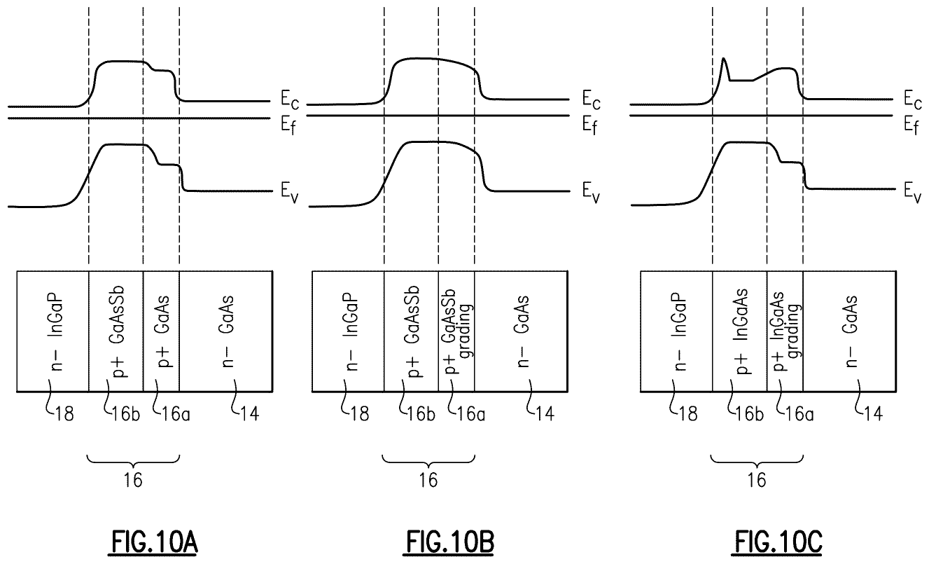

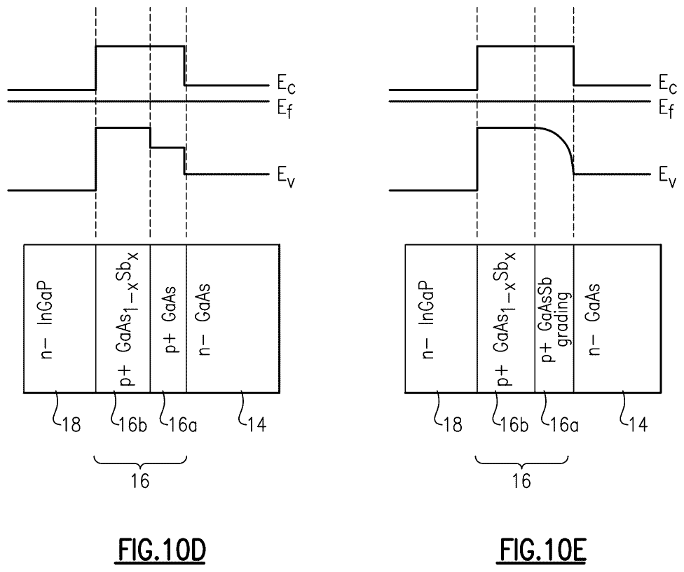

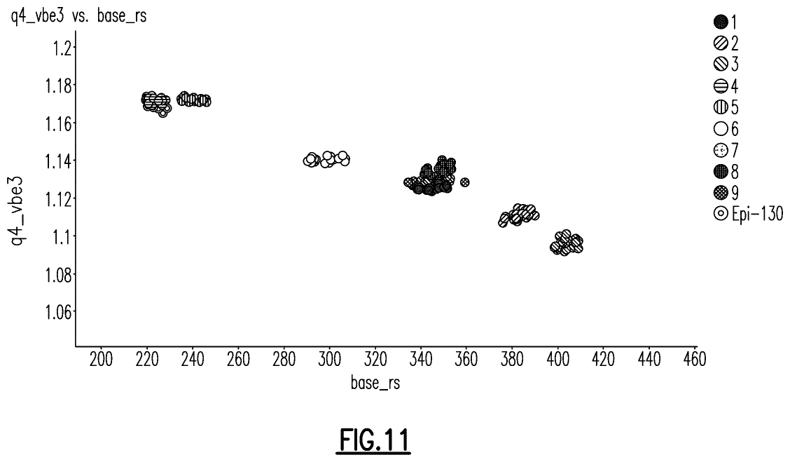

FIGS. 10A-10E show example emitter/base/collector stacks in examples of a heterojunction bipolar transistor (HBT) with bi-layer bases, and also shows respective energy levels (a conduction band edge energy (Ec), a valence band edge energy (Ev), and fermi level energy (Ef)) in the stacks. The stack in FIGS. 10A and 10D has an N-GaAs layer as the collector 14, a P+GaAs layer as the first layer 16a of the base 16, a P+GaAsSb layer as the second layer 16b of the base 16, and an N-InGaP as the emitter 18. The stack in FIGS. 10B and 10E has an N-GaAs layer as the collector 14, a grading P+GaAsSb layer as the first layer 16a of the base 16, a P+GaAsSb layer as the second layer 16b of the base 16, and an N-InGaP as the emitter 18. The stack in FIG. 10C has an N-GaAs layer as the collector 14, a grading P+InGaAs layer as the first layer 16a of the base 16, a P+InGaAs layer as the second layer 16b of the base 16, and an N-InGaP as the emitter 18. As shown in FIGS. 10A-10C, changes in the conduction band edge energy (Ec) and the valence band edge energy (Ev) between different layers may be visibly gradual in some devices. As shown in FIGS. 10D and 10E, changes in the conduction band edge energy (Ec) and the valence band edge energy (Ev) between different layers may be non-gradual or abrupt in some other devices.

The n-type doped InGaP layer of the emitter 18 can have In and Ga composition at around 50% so that it is lattice matched to GaAs. In FIGS. 10A and 10B, the second layer 16b adjacent to n-type InGaP emitter 18 can be a GaAs₁₋ₓSbₓ layer, and the first layer 16a adjacent to n-type GaAs collector 14 can be a p-type GaAs layer or a composition graded p-type GaAs₁₋ₓSbₓ layer, where, for example, the Sb composition grades from x at the interface between the two base layers 16a, 16b to zero or close to zero at the base-collector junction. Due to the reduced bandgap of the second base layer 16b with the incorporation of Sb, the turn-on voltage as well as Veeoffset can be reduced.

FIG. 11 is a graph showing turn-on voltage of an InGaP/GaAs₁₋ₓSbₓ/GaAs (emitter/base/collector) stack HBT with different Sb composition or concentration. In the graph of FIG. 11, data sets for concentrations of Sb at 0% (shading patterns labeled Epi-130 and 5), at about 0.1% (a shading pattern labeled 4), at about 2.25% (a shading pattern labeled 9), at about 3.3% (shading patterns labeled 1, 7, 8, 9), at about 4.6% (a shading pattern labeled 2), and at about 5.8% (a shading pattern labeled 3) are shown. The graph of FIG. 11 indicates that the higher the Sb composition, the higher base Rs (as shown in x-axis), and the lower turn-on voltage Vbe3 (as shown in y-axis). The Vbe3 decreases with the increase of Sb composition as shown in FIG. 11. The lattice constant of the GaAs₁₋ₓSbₓ layer, on the other hand, increases with the increase of Sb composition. The thickness of the GaAs₁₋ₓSbₓ layer can be controlled to avoid or mitigate introduction of dislocations. In some embodiments, an ideal thickness of the GaAs₁₋ₓSbₓ layer at 3-5% of Sb composition can be 700 Å or below. As mentioned herein, because hole mobility decreases with the increase of Sb composition, the sheet resistance of the GaAs₁₋ₓSbₓ layer may increase with the Sb composition increase. The first layer 16a of the base 16 (see FIGS. 8A, 8B, and 10A-10C) can reduce the overall base resistance in the HBT thereby achieving relatively low turn-on voltage without trading off the R_{b}. In some embodiments, the emitter/base/collector stack in an HBT can be InP/GaAs_{0.5}Sb_{0.5}/InP.

Various embodiments of the HBTs disclosed herein achieve a lower turn-on voltage Vbe without significantly degrading the base resistance (R_{b}) thereby preventing or mitigating creation of a soft knee. Any suitable combination of the principles and advantages disclosed herein can be implemented in any suitable manner. For example, the embodiments disclosed with respect to FIGS. 8A-10C may implement the ledge dimensions and the base thicknesses disclosed with respect to FIGS. 1-4.

Any of the embodiments disclosed herein can be implemented in a variety of electronic devices, such as a mobile device (e.g., a mobile phone having an architecture for communicating under the 3G, 4G, and/or 5G communications standards), which can also be referred to as a wireless device.

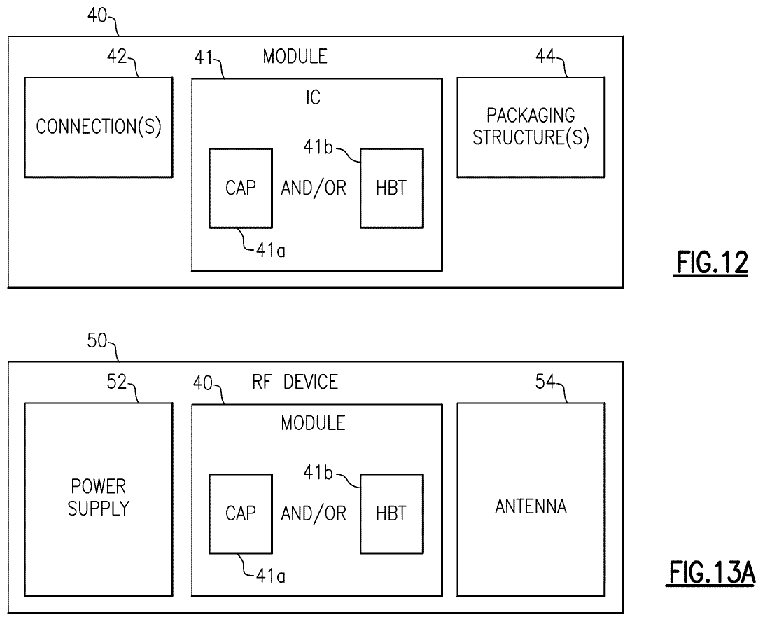

FIG. 12 schematically shows that a packaged module 40 can include an IC 41 having one or more capacitors 41a and one or more HBTs 41b, which can be any of the HBTs as described herein. In some embodiments, such an IC can be implemented on a die. The module 40 can further include one or more packaging structures 44 that provide, for example, a mounting substrate and protection for the IC 41. The module 40 can further include connection features 42 such as connectors and terminals configured to provide electrical connections to and from the IC 41.

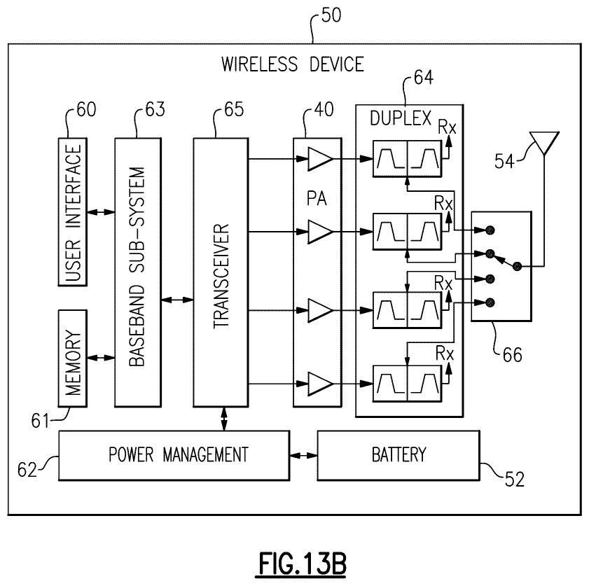

FIG. 13A schematically shows that in some embodiments, a component such as the module 40 of FIG. 12 can be included in an RF device 50. Such an RF device can include a wireless device such as a cellular phone, smart phone, tablet, or any other portable device configured for voice and/or data communication. In FIG. 13A, the module 40 is depicted as including one or more capacitors 41a and/or one or more HBTs 41b, which can be any of the HBTs as described herein. The RF device 50 is depicted as including other common components such an antenna 54, and also configured to receive or facilitate a power supply 52 such as a battery.

FIG. 13B shows a more specific example of how the wireless device 50 of FIG. 13A can be implemented. In FIG. 13B, an example wireless device 50 is shown to include a module 40 (e.g., a PA module) having one or more features as described herein. For example, the PA module 40 can include a plurality of HBT power amplifiers 41b configured to provide amplifications for RF signals associated with different bands and/or modes. The power amplifiers 41b on the PA module 40 can comprise one or more HBTs, which can be any of the HBTs described herein.

In the example wireless device 50, the PA module 40 can provide an amplified RF signal to the switch 66 (via a duplexer 64), and the switch 66 can route the amplified RF signal to an antenna 54. The PA module 40 can receive an unamplified RF signal from a transceiver 65 that can be configured and operated in known manners. The transceiver 65 can also be configured to process received signals. The transceiver 65 is shown to interact with a baseband sub-system 63 that is configured to provide conversion between data and/or voice signals suitable for a user and RF signals suitable for the transceiver 65. The transceiver 65 is also shown to be connected to a power management component 62 that is configured to manage power for the operation of the wireless device 50. Such a power management component can also control operations of the baseband sub-system 63 and other components of the wireless device 50.

The baseband sub-system 63 is shown to be connected to a user interface 60 to facilitate various input and output of voice and/or data provided to and received from the user. The baseband sub-system 63 can also be connected to a memory 61 that is configured to store data and/or instructions to facilitate the operation of the wireless device, and/or to provide storage of information for the user.

In some embodiments, the duplexer 64 can allow transmit and receive operations to be performed simultaneously using a common antenna 54. In FIG. 13B, received signals are shown to be routed to “Rx” paths that can include, for example, a low-noise amplifier (LNA).

The example duplexer 64 is typically utilized for frequency-division duplexing (FDD) operation. It will be understood that other types of duplexing configurations can also be implemented. For example, a wireless device having a time-division duplexing (TDD) configuration can include respective low-pass filters (LPF) instead of the duplexers, and the switch 66 can be configured to provide band selection functionality, as well as Tx/Rx (TR) switching functionality.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an car piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A bipolar junction transistor comprising:
a substrate;
a collector over the substrate;
a base over the collector, the base including a III-V ternary semiconductor alloy including first, second, and third elements, the III-V ternary semiconductor alloy having a narrower bandgap than a binary semiconductor alloy including only the first and second elements, at least a portion of the base having a differential concentration of the third element such that a concentration of the third element at a first location in the base is greater than at a second location in the base, the second location between the first location and the collector; and
an emitter over the base.

2. The bipolar junction transistor of claim 1 wherein the collector includes a gallium arsenide (GaAs) layer.

3. The bipolar junction transistor of claim 1 wherein the third element of the base is antimony (Sb) or indium (In).

4. The bipolar junction transistor of claim 1 wherein the III-V ternary semiconductor alloy of the base is gallium arsenide antimonide (GaAsSb) or indium gallium arsenide (InGaAs).

5. The bipolar junction transistor of claim 1 wherein the emitter includes an indium gallium phosphide (InGaP) layer.

6. The bipolar junction transistor of claim 1 wherein a concentration of the third element at the first location is in a range of 0.1% to 6% mole fraction.

7. The bipolar junction transistor of claim 6 wherein a concentration of the third element at the second location is zero.

8. The bipolar junction transistor of claim 1 wherein a concentration of the third element at a third location between the first and second locations is less than the concentration of the third element at the first location and greater than the concentration of the third element at the second location.

9. The bipolar junction transistor of claim 1 further comprising a sub-collector between the substrate and the collector.

10. The bipolar junction transistor of claim 1 wherein the base has a gradation of the concentration of the third element.

11. The bipolar junction transistor of claim 1 wherein a bandgap of the III-V ternary semiconductor alloy is in a range between 50% and 90% of a bandgap of the binary semiconductor alloy.

12. A bipolar junction transistor comprising:
a substrate;
a first n-type structure over the substrate;
a p-type structure over the first n-type structure, the p-type structure including a III-V ternary semiconductor alloy including first, second, and third elements, the ternary semiconductor alloy having a narrower bandgap than a binary semiconductor alloy consisting of the first and second elements, at least a portion of the p-type structure having a differential concentration of the third element such that a concentration of the third element at a first location in the p-type structure is greater than at a second location in the p-type structure, the second location between the first location and the first n-type structure; and
a second n-type structure over the p-type structure.

13. The bipolar junction transistor of claim 12 wherein the first n-type structure includes a gallium arsenide (GaAs) layer and the second n-type structure includes an indium gallium phosphide (InGaP) layer.

14. The bipolar junction transistor of claim 12 wherein the p-type structure includes a gallium arsenide antimonide (GaAsSb) layer or an indium gallium arsenide (InGaAs) layer.

15. The bipolar junction transistor of claim 12 wherein a concentration of the third element at the first location is in a range of 0.1% to 6% mole fraction of the III-V ternary semiconductor alloy.

16. The bipolar junction transistor of claim 12 further comprising a sub-collector between the substrate and the first n-type structure.

17. The bipolar junction transistor of claim 12 wherein the p-type structure has a gradation of the concentration of the third element.

18. A radio frequency device comprising:
a bipolar junction transistor power amplifier having a collector, a base structure over the collector, and an emitter over the base structure, the base including a III-V ternary semiconductor alloy including first, second, and third elements, the III-V ternary semiconductor alloy having a narrower bandgap than a binary semiconductor alloy including only the first and second elements, at least a portion of the base structure having a differential concentration of the third element such that a concentration of the third element at a first location in the base is greater than at a second location in the base, the second location between the first location and the collector; and
an antenna coupled to the bipolar junction transistor power amplifier.

19. The radio frequency device of claim 18 wherein the collector includes a gallium arsenide (GaAs) layer.

20. The radio frequency device of claim 18 wherein the third element of the base is antimony (Sb) or indium (In).

21. The radio frequency device of claim 18 wherein the III-V ternary semiconductor alloy of the base is gallium arsenide antimonide (GaAsSb) or indium gallium arsenide (InGaAs).
